(19) United States
(12) Patent Application Publication
(10) Pub. No.: US 2007/0194341 A1
(43) Pub. Date: Aug. 23, 2007

(54) Light emitting diode package

(75) Inventors: Myung Whun Chang, Seoul (KR); Jong Myeon Lee, Gwacheon (KR); Ho Sung Choo, Suwon (KR); Young Gon Park, Suwon (KR); Hai Sung Lee, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/709,135

(22) Filed: Feb. 22, 2007

(30) Foreign Application Priority Data
Feb. 22, 2006 (KR) 10-2006-0017391

(51) Int. Cl. H01L 33/00

(52) U.S. Cl. 257/99

(57) ABSTRACT

A light emitting diode package. A package substrate has first and second electrode structures and a light emitting diode is mounted on the package substrate and electrically connected to the first and second electrode structures. A resin encapsulant is made of a transparent resin to seal the light emitting diode. A plurality of transparent spherical particles having a refractive index higher than the transparent resin are dispersed in the resin encapsulant.

### CLAIM OF PRIORITY

This application claims the benefit of Korean Patent Application No. 2005-0017391 filed on Feb. 22, 2006, in the Korean Intellectual Property Office, the disclosure of which is incorporated herein by reference.

### BACKGROUND OF THE INVENTION

1. Field of the Invention

The present invention relates to a Light Emitting Diode (LED) package and, more particularly, to an LED package which incorporates an optical means having a light focusing function in a resin encapsulant to improve light extraction efficiency.

2. Description of the Related Art

In general, an LED has merits such as excellent monochromatic peak wavelength, excellent light efficiency and facilitation of miniaturization, and thus widely used as various display devices and light sources. A typical LED package has a structure in which an LED is protected by a transparent resin encapsulant. In particular, the resin encapsulant of a white LED package has phosphor powder dispersed therein to convert the wavelength of light, thereby obtaining white light.

FIG. 1 is a sectional view illustrating a conventional LED package.

Referring to FIG. 1, the LED package 10 includes a lower package substrate 11a with first and second electrode structures 13a and 13b formed thereon and an upper package substrate 11b with a cavity formed therein. In the cavity, a light emitting diode chip 15 is mounted. An LED chip 15 can be a flip-chip structure including an LED 15a and a chip substrate 15b. Both electrodes (not shown) of the LED chip 15 can be connected to the upper ends of the first and second electrode structures 13a and 13b by wires, respectively. Inside the cavity provided in the upper package substrate 11b, a resin encapsulant 17 is formed to surround the LED chip 15.

As the light (indicated by arrows) of the LED chip 15 is emitted in all directions, a great portion of light S does not propagate directly in a desired direction but in sideward directions. The light S propagating in sideward directions can be absorbed into side surfaces of the cavity or can be directed upward via a separate reflecting means, which however lengthens the paths, causing a significant loss inside the resin encapsulant 17.

In addition, since the refractive index of the material of the resin encapsulant 17 is higher than the air, the amount of light extracted from the interface between the ambient atmosphere and the resin encapsulant 17 is limited by the critical angle due to the difference in the refractive indices. Due to such conditions of the light extraction critical angle, when the light eventually reaches the surface of the resin encapsulant via slanted paths, it is difficult for the light to be effectively extracted.

### SUMMARY OF THE INVENTION

The present invention has been made to solve the foregoing problems of the prior art and therefore an aspect of the present invention is to provide a Light Emitting Diode (LED) package, which incorporates a new optical means in a resin encapsulant to redirect the light from an LED chip upward to be more effectively extracted, thereby improving light emission efficiency.

According to an aspect of the invention, the invention provides a light emitting diode package which includes: a package substrate having first and second electrode structures; a light emitting diode mounted on the package substrate and electrically connected to the first and second electrode structures; a resin encapsulant made of a transparent resin and encapsulating the light emitting diode; and a plurality of transparent spherical particles dispersed in the resin encapsulant, the spherical particles having a refractive index higher than that of the transparent resin.

Preferably, the transparent spherical particles have a refractive index lower than that of the light emitting diode, and considering a case of a typical nitride light emitting diode, it is preferable that the transparent spherical particles have a refractive index of 1.5 to 2.4.

Preferably, the transparent spherical particles are sized 0.5 to 8 μm. If sized less than 0.5 μm, the light focusing effect is too weak, and if sized larger than 8 μm, the light efficiency can be lowered due to light scatter problems.

Preferably, the transparent spherical particles may be polystyrene beads. In addition, the resin encapsulant may further include phosphor powder dispersed therein. The resin encapsulant may be made of one selected from the group consisting of a silicone resin, an epoxy resin and a mixture thereof.

In an exemplary embodiment, the resin encapsulant may be composed of a first resin encapsulant having a first refractive index and a second encapsulant having a second refractive index, in which the first refractive index is greater than the second refractive index and the first resin encapsulant seals the light emitting diode mounted on the package substrate and the second resin encapsulant is formed on the first resin encapsulant. In this case, the transparent spherical particles are disposed in the second resin encapsulant and have a refractive index larger than that of the second resin encapsulant.

Various structures of package substrates can be adopted in the present invention, but preferably, the package substrate may have a cavity with an upward-inclined inner wall. In this case, the cavity provides an area for mounting the light emitting diode and defines an area for forming the resin encapsulant.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a sectional view illustrating a conventional LED package;

FIG. 2 is a sectional view illustrating an LED package according to an embodiment of the present invention;

FIG. 3 is a schematic view illustrating the light focusing principle by a transparent spherical particle adopted in the present invention;

FIG. 4 is a sectional view illustrating a LED package according to another embodiment of the present invention; and

FIG. 5 is a Scanning Electron Microscope (SEM) picture showing polystyrene beads used in the present invention.

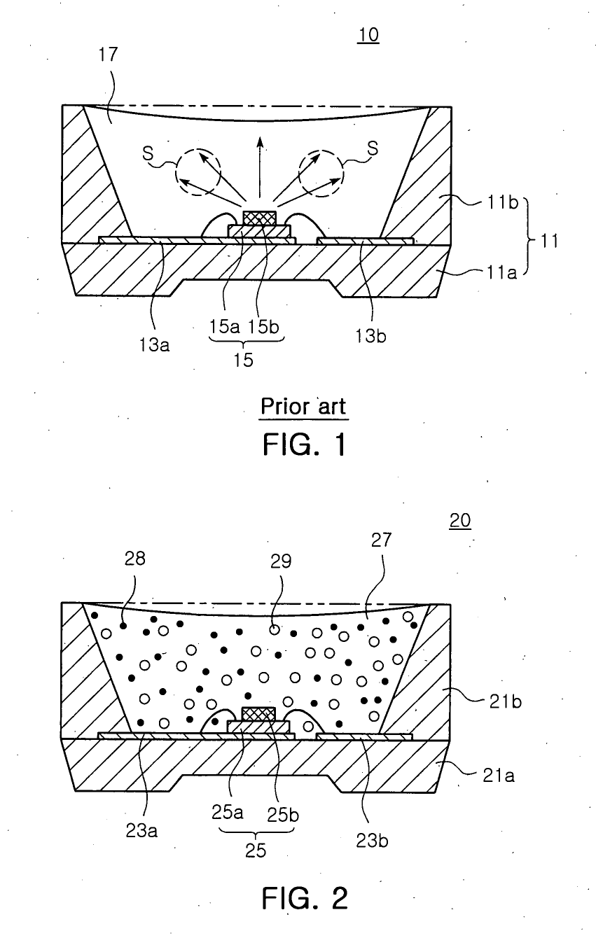

### DETAILED DESCRIPTION OF THE PREFERRED EMBODIMENT

Exemplary embodiments of the present invention will now be described in detail with reference to the accompanying drawings.

FIG. 2 is a sectional view illustrating an LED package according to an embodiment of the present invention.

Referring to FIG. 2, the LED package 20 includes a package substrate 21 with an LED chip 25 mounted thereon. As shown, the LED chip 25 can include an LEd 25b and a submount substrate 25a on which the LED 25b is flip chip bonded, but the present invention is not limited thereto. The package substrate 21 includes a lower package substrate 21a with first and second electrode structures 23a and 23b formed thereon and an upper package substrate 21b with a cavity formed therein. Merely the first and second electrode structures 23a and 23b on an upper surface of the lower package substrate are illustrated, but as it is apparent to a person ordinarily skilled in the art, they may be connected to an electrode pad (not shown) formed on a bottom surface through a via, etc. to electrically connect the package to an outside power source.

Both electrodes (not shown) of the LED chip 25 can be connected to the first and second electrode structures 23a and 23b by wires, respectively. A resin encapsulant 27 is formed in the cavity provided in the upper package substrate 21b to surround the LED chip 25. The resin encapsulant 27 can be made of a transparent resin such as a silicone resin, an epoxy resin and a mixture thereof.

The resin encapsulant 27 adopted in this embodiment includes a plurality of phosphor particles 28 and transparent spherical particles 29 dispersed therein. The phosphor 28 functions to convert the wavelength of the LED to another wavelength and can be used mainly to obtain white light.

The transparent spherical particles 29 adopted in the present invention have a refractive index higher than that of the surrounding resin encapsulant 27. The transparent spherical particles 29 having a relatively higher refractive index can act as an optical means which focuses light to adjust the light paths in upward directions.

More specifically, the transparent spherical particles 29 which have a relatively higher refractive index than the surrounding resin, focus not only the light incident via straight paths but also the light incident via slanted paths, similar to a convex lens, thereby increasing the possibility of light propagating directly upward.

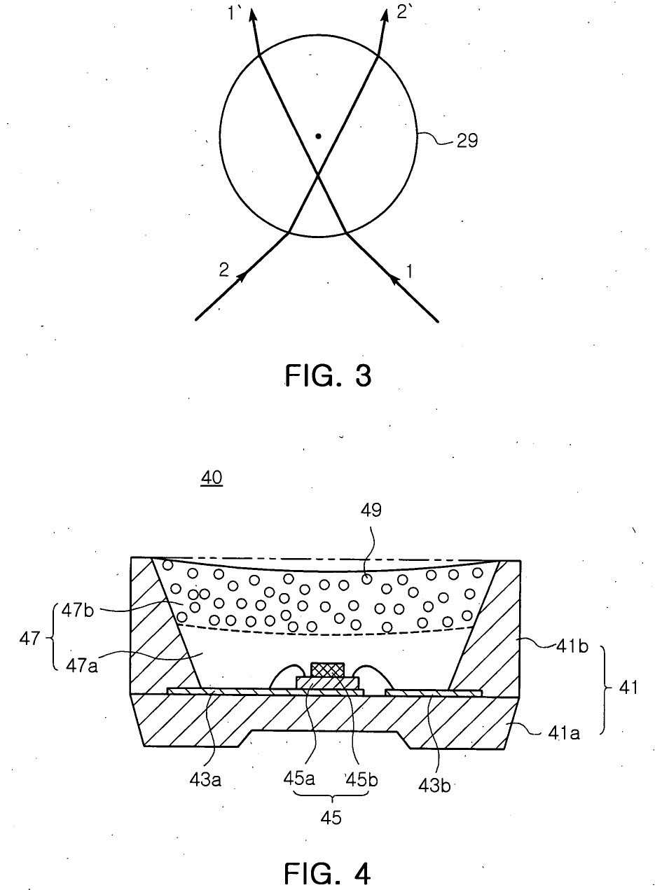

FIG. 3 illustrates the paths of light being incident via slanted paths into the transparent spherical particle 29.

As shown in FIG. 3, the light 1 and 2, which is incident via slanted paths, is focused by the transparent spherical particle 29 having a higher refractive index than the surrounding, thereby redirected to exit through the paths 1′ and 2′ closer to the central axis of the sphere. Therefore, by the light focusing function of the transparent spherical particles adopted in the present invention, the light that ordinarily propagates uniformly in all directions can be more effectively redirected to propagate upward or in the opposite directions from the LED chip 25, the light source.

As a result, the LED package of the present invention can decrease the amount of light reaching the inner sidewall, etc. while increasing the amount of light propagating upward. Also, the light in upward directions can reach the surface of the resin encapsulant 27 in greater incident angles, significantly improving light extraction efficiency.

Such light focusing function is possible since the transparent particles 29 are spherical and have a refractive index higher than the surrounding resin encapsulant 27. Preferably, the transparent spherical particles 29 have a refractive index lower than that of the LED 25b which can be disposed below the particles. Considering a typical case of a nitride LED, it is preferable that the transparent spherical particles have a refractive index lower than 2.4, which is the refractive index of GaN.

Preferably, the transparent spherical particles 29 can be sized 0.5 to 8 μm. If sized less than 0.5 μm, the particles have a weak light focusing effect, and if sized larger than 8 μm, the substantial light extraction efficiency may be lowered due to light scatter problems.

Since the transparent spherical particles adopted in the present invention are based on a principle of converting the light paths through a light focusing effect, the degree of conversion varies according to the positions of the transparent spherical particles. For example, the transparent spherical particles disposed above the light emitting diode can more effectively convert the light paths in desired upward directions.

Based on this principle, the resin encapsulant can be formed in a multiple-layer structure with the transparent spherical particles disposed above the light emitting diode. In particular, in the multiple-layer structure, the refractive indices can be configured smaller toward upper resin layers, increasing the total reflection critical angles in a stepwise fashion, thereby further improving the light extraction efficiency. Such an embodiment is illustrated in FIG. 4.

Referring to FIG. 4, the light emitting diode package 40 includes a package substrate 41 with an LED chip 45 mounted thereon. Similar to the structure shown in FIG. 3, the LED chip 45 can include an LED 45b and a submount substrate 45a on which the LED 45b is flip chip bonded. The package substrate 41 includes a lower package substrate with first and second electrode structures 43a and 43b and an upper package substrate 41b with a cavity provided therein. Both electrodes (not shown) of the LED chip 45 can be connected to the first and second electrode structures 43a and 43b by wires, respectively.

Inside the cavity provided in the upper package substrate 41b, a resin encapsulant 47 is formed to surround the LED chip 45. The resin encapsulant 47 can be composed of first and second resin encapsulants 47a and 47b made of resins with different refractive indices. The first resin encapsulant 47a is made of a transparent resin having a refractive index lower than that of the light emitting diode 45b and higher than that of the second resin encapsulant 47b.

In addition, the second resin encapsulant 47b includes a plurality of transparent spherical particles 49 dispersed therein. The transparent spherical particles 49 have a refractive index higher than the surrounding second resin encapsulant 47b. Similar conditions on the refractive index and the particle size can be applied with reference to the description related to FIG. 2.

The transparent spherical particles 49 adopted in this embodiment focus light to adjust the light paths in upward directions. Although the transparent spherical particles are disposed limitedly in the second resin encapsulant 47b in this embodiment, they can more effectively convert the paths of the incident light in desired upward directions. In addition, in this embodiment, the structure of the resin encapsulant 47 can be configured such that the first and second resin encapsulants 47a and 47b have refractive indices smaller to the upper part thereof, thereby increasing the total reflection critical angles of exiting light in a stepwise fashion. This in turn improves light extraction efficiency.

The operations and effects of the present invention will be more specifically explained through Examples.

### EXAMPLE 1

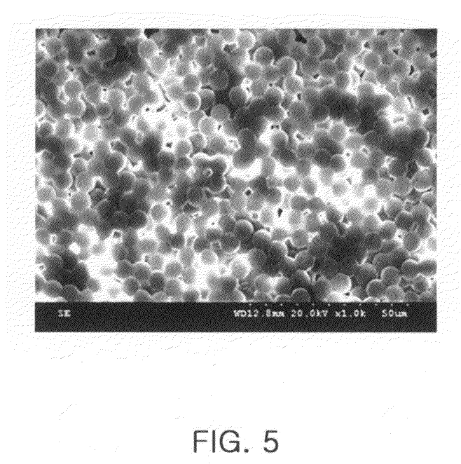

In this Example, 7 side-view LED packages were fabricated similar to the one shown in FIG. 2. A Silicone resin (refractive index: 1.56) was used as a main material for each of the resin encapsulant. 10 vol % of a polystyrene-beads liquid including 10 wt % of the polystyrene beads (see FIG. 5) was added and mixed into the silicone resin to form the resin encapsulants.

The polystyrene beads used in this Example have a particle size of about 6.4 μm and a refractive index of about 1.59.

### EXAMPLE 2

Under the same conditions as the aforedescribed Example 1, 7 LED packages were fabricated. In this Example, however, 20 vol % of the polystyrene-beads liquid was added to the silicone resin to form each of the resin encapsulants.

### COMPARATIVE EXAMPLE

Under the same conditions as in Example 1, 7 LED packages were fabricated. In this Example, however, the polystyrene-beads liquid was not added and only the silicone resin was used to form the resin encapsulants.

Then, the luminance was measured for the 7 LED packages (total of 21) produced under the different conditions. The results are as shown in Table 1 (unit: mCd).

TABLE 1

| | A | B | C | D | E | F | G | Mean |
|---|---|---|---|---|---|---|---|---|
| Example 1 | 230 | 210 | 210 | 220 | 210 | 190 | 200 | 210 |
| Example 2 | 220 | 210 | 220 | 220 | 210 | 210 | 210 | 214 |
| Comparative | 170 | 190 | 200 | 180 | 180 | 180 | 180 | 183 |

Referring to Table 1, in the Comparative Example, the mean luminance was about 180 mCd, as compared to the high mean values of about 210 mCd and 214 mCd by the LED packages according to Examples 1 and 2, respectively. Overall, Examples 1 and 2 exhibited significant effects of improved luminance, in which the luminance was improved by about 15% and 17% by the polystyrene beads, respectively. This can be understood that the light extraction efficiency was improved by the light focusing function of the spherical beads, as mentioned hereinabove.

According to the present invention as set forth above, transparent spherical particles, which have a higher refractive index than the surroundings, are dispersed in a resin encapsulant as a new optical means, thereby redirecting the light from an LED chip to propagate in desired upward directions. Therefore, a greater amount of light can directly propagate upward without going by way of another reflecting surface, decreasing the optical paths while increasing the incident angles of light propagating toward the surface of the resin encapsulant, thereby significantly improving light extraction efficiency.

While the present invention has been shown and described in connection with the exemplary embodiments, it will be apparent to those skilled in the art that modifications and variations can be made without departing from the spirit and scope of the invention as defined by the appended claims.

What is claimed is:

1. A light emitting diode package comprising:
a package substrate having first and second electrode structures;
a light emitting diode mounted on the package substrate and electrically connected to the first and second electrode structures;
a resin encapsulant made of a transparent resin and encapsulating the light emitting diode; and
a plurality of transparent spherical particles dispersed in the resin encapsulant, the spherical particles having a refractive index higher than that of the transparent resin.

2. The light emitting diode package according to claim 1, wherein the transparent spherical particles have a refractive index lower than that of the light emitting diode.

3. The light emitting diode package according to claim 2, wherein the transparent spherical particles have a refractive index of 1.5 to 2.4.

4. The light emitting diode package according to claim 1, wherein the transparent spherical particles are sized 0.5 to 8 μm.

5. The light emitting diode package according to claim 1, wherein the transparent spherical particles comprise polystyrene beads.

6. The light emitting diode package according to claim 1, wherein the resin encapsulant further comprises phosphor powder dispersed therein.

7. The light emitting diode package according to claim 1, wherein the resin encapsulant comprises one selected from the group consisting of a silicone resin, an epoxy resin and a mixture thereof.

8. The light emitting diode package according to claim 1, wherein the resin encapsulant comprises a first resin encapsulant having a first refractive index and a second encapsulant having a second refractive index, wherein the first refractive index is greater than the second refractive index, wherein the first resin encapsulant seals the light emitting diode mounted on the package substrate and the second resin encapsulant is formed on the first resin encapsulant, and
wherein the transparent spherical particles are disposed in the second resin encapsulant and have a refractive index larger than that of the second resin encapsulant.

9. The light emitting diode package according to claim 1, wherein the package substrate comprises a cavity with an upward-inclined inner wall, and the cavity provides an area for mounting the light emitting diode and defines an area for forming the resin encapsulant.
